(19) United States
(12) Patent Application Publication
(10) Pub. No.: US 2026/0271341 A1
(43) Pub. Date: Sep. 10, 2026

(54) DISPLAY DEVICE AND METHOD OF MANUFACTURING THE SAME

(71) Applicant: SAMSUNG DISPLAY CO., LTD., YONGIN-SI (KR)

(72) Inventor: Hyun Eok SHIN, Yongin-si (KR)

(21) Appl. No.: 19/343,391

(22) Filed: Sep. 29, 2025

(30) Foreign Application Priority Data
Mar. 5, 2025 (KR) 10-2025-0028022
Apr. 4, 2025 (KR) 10-2025-0043808

(51) Int. Cl. H10D 30/67; H10K 59/12; H10K 102/00

(52) U.S. Cl. CPC H10D 30/6755; H10D 30/6737; H10K 59/1201; H10K 2102/351

(57) ABSTRACT

A display device includes a substrate, a semiconductor layer disposed on the substrate, a gate electrode that overlaps a channel area of the semiconductor layer in a thickness direction of the substrate, a gate insulating layer, and a metal oxide film. The gate insulating layer is disposed between the semiconductor layer and the gate electrode and insulates the semiconductor layer from the gate electrode. The metal oxide film is disposed on the gate electrode and the gate insulating layer. A first thickness of the metal oxide film disposed on the gate electrode is greater than a second thickness of the metal oxide film disposed on the gate insulating layer.

### CROSS-REFERENCE TO RELATED APPLICATIONS

This application claims priority under 35 U.S.C. § 119 to Korean Patent Application No. 10-2025-0028022 filed on March 5, 2025, and Korean Patent Application No. 10-2025-0043808 filed on April 4, 2025, the disclosures of which are incorporated by reference herein in their entireties.

### TECHNICAL FIELD

Embodiments of the present disclosure relate to a display device and a method of manufacturing the same.

### DISCUSSION OF RELATED ART

As the information age progresses, demand has increased for display devices capable of presenting images in a variety of formats. These display devices may include flat panel types such as liquid crystal displays (LCDs), field emission displays (FEDs), and light-emitting displays. Among light-emitting displays, examples include organic light-emitting displays that incorporate organic light-emitting elements, inorganic light-emitting displays that utilize inorganic light-emitting elements such as inorganic semiconductors, and micro light-emitting displays that employ micro-scale light-emitting elements.

Display devices typically include a light-emitting diode and multiple thin-film transistors (TFTs) electrically connected to the diode. These thin-film transistors may be formed using polycrystalline silicon semiconductors or oxide semiconductors. Polycrystalline silicon-based TFTs may provide stable driving currents, while oxide semiconductor-based TFTs may offer fast turn-on response and excellent off-current characteristics.

### SUMMARY

Embodiments of the present disclosure provide a display device including an oxide semiconductor thin-film transistor having improved hydrogen blocking ability by forming a metal oxide film entirely covering a gate and an insulating layer by an anodizing method, and a method of manufacturing the same.

According to an embodiment of the present disclosure, a display device includes a substrate, a semiconductor layer disposed on the substrate, a gate electrode that overlaps a channel area of the semiconductor layer in a thickness direction of the substrate, a gate insulating layer, and a metal oxide film. The gate insulating layer is disposed between the semiconductor layer and the gate electrode and insulates the semiconductor layer from the gate electrode, the metal oxide film is disposed on the gate electrode and the gate insulating layer, and a first thickness of the metal oxide film disposed on the gate electrode is greater than a second thickness of the metal oxide film disposed on the gate insulating layer.

The gate electrode may include aluminum (Al).

The metal oxide film may include aluminum oxide (AlₓO_{y}).

The metal oxide film may be formed by an anodizing method.

The semiconductor layer may include an oxide semiconductor.

A thickness of the metal oxide film may be about 100 Å or more.

The display device may further include a buffer layer disposed between the substrate and the semiconductor layer and including anodized aluminum oxide (AlₓO_{y}).

According to an embodiment of the present disclosure, a method of manufacturing a display device includes forming a semiconductor layer on a substrate, forming a gate insulating layer on the semiconductor layer, forming a gate electrode on the gate insulating layer in an area which overlaps a channel area of the semiconductor layer in a thickness direction of the substrate, forming a metal film on the gate insulating layer and the gate electrode, and forming a metal oxide film by oxidizing the metal film using an anodizing method.

A first thickness of the metal oxide film formed on the gate electrode may be greater than a second thickness of the metal oxide film formed on the gate insulating layer.

The gate electrode and the metal film may include the same metal.

The gate electrode may include aluminum (Al).

The metal oxide film may include aluminum oxide (AlₓO_{y}).

The semiconductor layer may include an oxide semiconductor.

A thickness of the metal oxide film may be about 100 Å or more.

The method may further include, before forming the semiconductor layer, forming a second metal film on the substrate, and before forming the semiconductor layer, forming a second metal oxide film by oxidizing the second metal film using the anodizing method.

The second metal film includes aluminum (Al), and the second metal oxide film may include aluminum oxide (AlₓO_{y}).

According to an embodiment of the present disclosure, an electronic device includes a display device configured to provide an image, and a processor configured to transmit an image data signal to the display device. The display device includes a substrate, a semiconductor layer disposed on the substrate, a gate electrode that overlaps a channel area of the semiconductor layer in a thickness direction of the substrate, a gate insulating layer disposed between the semiconductor layer and the gate electrode and insulating the semiconductor layer from the gate electrode, and a metal oxide film disposed on the gate electrode and the gate insulating layer. A first thickness of the metal oxide film disposed on the gate electrode may be greater than a second thickness of the metal oxide film disposed on the gate insulating layer.

The gate electrode may include aluminum (Al), and the metal oxide film may include aluminum oxide (AlₓO_{y}).

The metal oxide film may be formed using an anodizing method.

The semiconductor layer may include an oxide semiconductor.

Referring to a display device according to embodiments of the present disclosure, the metal oxide film may be formed by the anodizing method to effectively block inflow of hydrogen. For example, the anodizing method may result in a fast process and densely forming the metal oxide film. Since the metal oxide film may effectively block hydrogen, reliability of the thin-film transistor layer may be improved.

In addition, the metal oxide film may be arranged more thickly on a gate electrode, thereby preventing a hilock phenomenon.

### BRIEF DESCRIPTION OF THE DRAWINGS

The above and other aspects and features of the present disclosure will become more apparent by describing in detail embodiments thereof with reference to the accompanying drawings, in which:

FIG. 1 is a plan view illustrating a display device according to an embodiment;

FIG. 2 is a side view illustrating a display device according to an embodiment;

FIG. 3 is an equivalent circuit diagram illustrating a subpixel according to an embodiment;

FIG. 4 is a cross-sectional view illustrating a display panel according to an embodiment;

FIG. 5 is an enlarged cross-sectional view of an area A of FIG. 4, illustrating a structure of a thin-film transistor;

FIG. 6 is a flowchart illustrating a method of manufacturing a display device according to an embodiment;

FIG. 7 is a cross-sectional view illustrating a substrate and a semiconductor layer in operation S100 of FIG. 6;

FIG. 8 is a cross-sectional view illustrating a substrate, a semiconductor layer, and a gate insulating layer in operation S200 of FIG. 6;

FIG. 9 is a cross-sectional view illustrating a substrate, a semiconductor layer, a gate insulating layer, and a gate electrode in operation S300 of FIG. 6;

FIG. 10 is a cross-sectional view showing a substrate, a semiconductor layer, a gate insulating layer, a gate electrode, and a metal film in operation S400 of FIG. 6;

FIG. 11 is a cross-sectional view illustrating a substrate, a semiconductor layer, a gate insulating layer, a gate electrode, and a metal oxide film in operation S500 of FIG. 6;

FIG. 12 is a schematic diagram illustrating a method of anodizing aluminum;

FIG. 13 is a transmission electron microscope (TEM) image of a cross-section of anodized aluminum;

FIG. 14 is a cross-sectional view illustrating a substrate and a second metal film;

FIG. 15 is a view illustrating that a second metal film formed on a substrate is oxidized to a second metal oxide film using an anodizing method;

FIG. 16 is a block diagram of an electronic device according to an embodiment; and

FIG. 17 illustrates schematic diagrams of an electronic device according to various embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure provide a display device and a method of manufacturing the same in which a metal oxide film is formed over a gate electrode and a gate insulating layer in a configuration that may improve hydrogen barrier characteristics and thermal stability of a thin-film transistor. For example, the metal oxide film may be formed by anodizing a metal film that is disposed on both the gate electrode and the gate insulating layer. Due to the nature of the anodizing process, the thickness of the resulting metal oxide film over the gate electrode may be greater than the thickness of the film over the gate insulating layer.

In an embodiment, the gate electrode may include aluminum, and the metal oxide film may include aluminum oxide (AlxOy). Because both the aluminum gate electrode and the deposited metal film participate in the anodization process, oxidation proceeds more deeply over the gate electrode, resulting in a relatively thicker aluminum oxide layer in that region. This asymmetry in film thickness may contribute to improved hydrogen-blocking performance in areas where hydrogen diffusion is most likely to impact the electrical characteristics of the oxide semiconductor layer.

The thickened metal oxide film above the gate electrode may also mitigate a hilock phenomenon, in which localized protrusions may form on an aluminum electrode during high-temperature processing. By oxidizing the aluminum surface into a dense metal oxide, the anodized film may reduce the likelihood of such thermal deformation without requiring additional high-resistance metal layers. Accordingly, embodiments of the present disclosure may improve transistor reliability while maintaining favorable process simplicity and electrical conductivity.

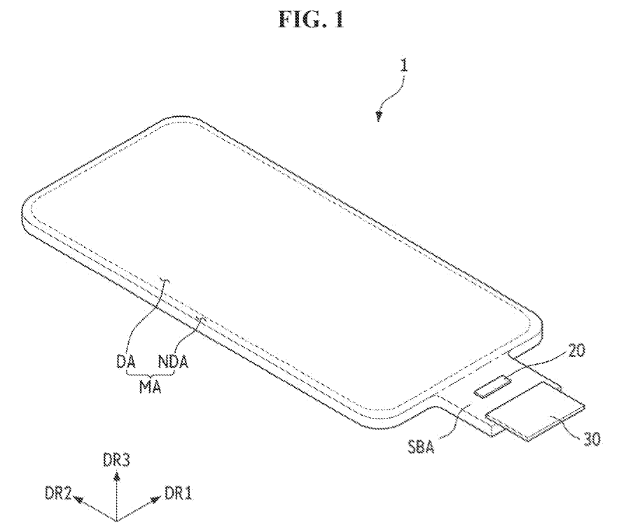

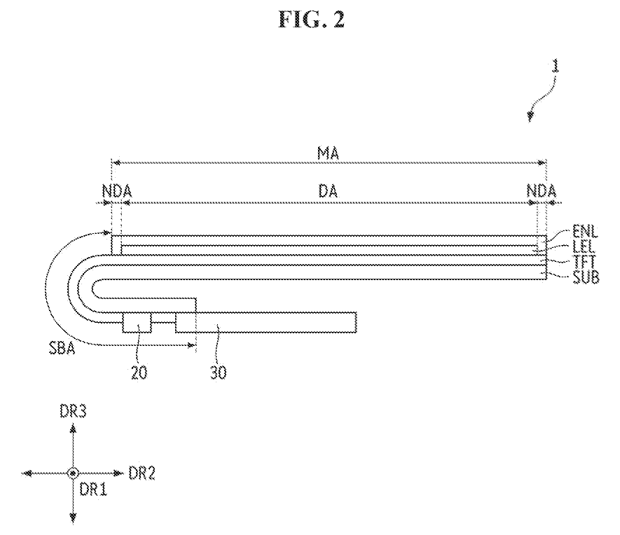

FIG. 1 is a plan view illustrating a display device according to an embodiment. FIG. 2 is a side view illustrating a display device according to an embodiment.

Referring to FIG. 1, a display device 1 according to an embodiment is a device that displays a moving image (e.g., a video) or a still image, and may be used as a display screen of various products such as, for example, a television, a laptop computer, a monitor, an advertising board, and an Internet of Things (IoT) device, as well as portable electronic devices such as, for example, a mobile phone, a smartphone, a tablet computer, a smart watch, a watch phone, a mobile communication terminal, an electronic diary, an electronic book, a portable multimedia player (PMP), a navigator and an ultra mobile PC (UMPC).

The display device 1 according to an embodiment may be a light-emitting display device such as, for example, an organic light-emitting display device using an organic light-emitting diode, a quantum dot light-emitting display device including a quantum dot light-emitting layer, an inorganic light-emitting display device including an inorganic semiconductor, and a micro or nano light-emitting display device using a micro or nano light-emitting diode (micro or nano LED). The following description will be based on that the display device 1 is an organic light-emitting display device. However, embodiments of the present disclosure are not limited thereto.

The display device 1 may include a display panel 100, a display driving circuit 20, and a circuit board 300.

The display panel 100 may be formed in a rectangular plane having a short side in a first direction DR1 and a long side in a second direction DR2 crossing the first direction DR1. Also, the display panel 100 may have a thickness in a third direction DR3 crossing the first direction DR1 and the second direction DR2. A corner where the short side in the first direction DR1 and the long side in the second direction DR2 meet may be rounded to have a curvature, or may be formed at a right angle. The planar shape of the display panel 100 is not limited to the rectangular shape, and may be formed in another polygonal shape, a circular shape or an oval shape. The display panel 100 may be formed to be flat, but is not limited thereto. For example, the display panel 100 may include a curved portion formed at left and right ends, having a constant curvature or a variable curvature. In addition, the display panel 100 may be flexibly formed to be curved, twisted, bent, folded or rolled.

The display panel 100 may include a main area MA and a sub-area SBA.

The main area MA may include a display area DA in which an image is displayed and a non-display area NDA that is a peripheral area of the display area DA. The display area DA may occupy most of the main area MA. The display area DA may be at the center of the main area MA. The non-display area NDA may be arranged to be adjacent to the display area DA. The non-display area NDA may be an outer area of the display area DA. The non-display area may be arranged to surround the display area DA. The non-display area NDA may be an edge area of the display panel 100. A plurality of pixels may be disposed in the display area DA to display an image. The display area DA may be an area that includes pixels to display an image. For example, the display area DA may include pixel areas in which the pixels are arranged.

The sub-area SBA may extend from one side of the main area MA in the first direction DR1. A length of the sub-area SBA in the first direction DR1 may be less than a length of the main area MA in the first direction DR1. A length of the sub-area SBA in the second direction DR2 may be less than a length of the main area MA in the second direction DR2, or may be substantially the same as the length of the main area MA in the second direction DR2. The sub-area SBA may be bent, and may be disposed below the display panel 100. In this case, the sub-area SBA may overlap the main area MA in the third direction DR3.

The display driving circuit 20 may generate signals and voltages that drive the display panel 100. The display driving circuit 20 may be formed as an integrated circuit (IC) and attached to the sub-area SBA of the display panel 100 in, for example, a chip on glass (COG) mode, a chip on plastic (COP) mode, or an ultrasonic bonding mode. In an embodiment, the display driving circuit 20 may be attached onto the circuit board 30 in a chip on film (COF) mode.

The circuit board 30 may be attached to one end of the sub-area SBA of the display panel 100. Thus, the circuit board 30 may be electrically connected to the display panel 100 and the display driving circuit 20. The display panel 100 and the display driving circuit 20 may receive digital video data, timing signals, and driving voltages through the circuit board 30. The circuit board 30 may be, for example, a flexible printed circuit board, a printed circuit board, or a flexible film such as a chip on film.

A lower portion of the display panel 100 may further include a light blocking layer that absorbs externally incident light, a buffer layer that absorbs external impact from outside, and a heat dissipation layer that efficiently dissipates heat from the display panel 100.

The light blocking layer may prevent transmission of light to prevent components below the light blocking layer from being visually recognized from an upper portion of the display panel 100. The light blocking layer may include a light absorbing material such as a black pigment or a black dye.

The buffer layer may absorb an external impact to prevent the display panel 100 from being damaged. The buffer layer may include a single layer or a plurality of layers. For example, the buffer layer may include a polymer resin such as polyurethane, polycarbonate, polypropylene and polyethylene, or may include a material having elasticity such as a rubber, a urethane-based material, or a sponge formed by foaming an acrylic-based material.

The heat dissipation layer may include a first heat dissipation layer including graphite or carbon nanotubes and a second heat dissipation layer including a thin metal film such as, for example, copper, nickel, ferrite or silver, which may shield electromagnetic waves and have excellent thermal conductivity.

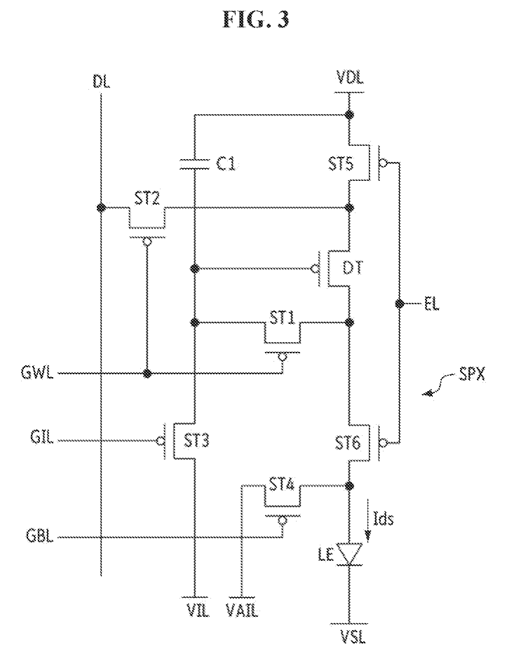

FIG. 3 is an equivalent circuit diagram illustrating a subpixel according to an embodiment.

Referring to FIG. 3, a subpixel SPX according to an embodiment may be connected to scan lines GWL, GIL and GBL, an emission control line EL, and a data line DL. For example, the subpixel SPX may be connected to a write scan line GWL, an initialization scan line GIL, a bias scan line GBL, the emission control line EL, and the data line DL.

The subpixel SPX according to an embodiment includes a driving transistor DT, switch elements, a capacitor C1, and a light-emitting element LE. The switch elements include first to sixth transistors ST1, ST2, ST3, ST4, ST5 and ST6.

The driving transistor DT includes a gate electrode, a first electrode, and a second electrode. The driving transistor DT controls a drain-source current Ids (hereinafter, referred to as a “driving current”) flowing between the first electrode and the second electrode in accordance with a data voltage applied to the gate electrode.

The light-emitting element LE may be a micro light-emitting diode.

The light-emitting element LE emits light in accordance with the driving current Ids. The amount of light emitted from the light-emitting element LE may be proportional to the driving current Ids. An anode electrode of the light-emitting element LE may be connected to a first electrode of the fourth transistor ST4 and a second electrode of the sixth transistor ST6, and a cathode electrode may be connected to a second power line VSL to which a second power voltage is applied.

The capacitor C1 is formed between the gate electrode of the driving transistor DT and a first power line VDL to which a first power voltage is applied. The first power voltage may be a voltage having a higher level than the second power voltage. One electrode of the capacitor C1 may be connected to the gate electrode of the driving transistor DT, and the other electrode thereof may be connected to the first power line VDL.

The driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. In this case, an active layer of each of the driving transistor DT, the second transistor ST2, the fourth transistor ST4, the fifth transistor ST5, and the sixth transistor ST6, which are formed as the p-type MOSFETs, may include polysilicon, and an active layer of each of the first transistor ST1 and the third transistor ST3, which are formed as the n-type MOSFETs, may include an oxide semiconductor. Also, since the first transistor ST1 and the third transistor ST3 are formed as n-type MOSFETs, the first transistor ST1 may be turned on when a scan signal of a gate high voltage is applied, and the third transistor ST3 may be turned on when an initialization scan signal of a gate high voltage is applied. In contrast, the second transistor ST2, the fourth transistor ST4, the fifth transistor ST5, and the sixth transistor ST6 are formed as p-type MOSFETs, and thus, may be turned on when a scan signal and an emission control signal of a gate low voltage are applied.

When the fourth transistor ST4 is formed as an n-type MOSFET, and the other transistors DT, ST1, ST2, ST3, ST5, and ST6 are formed as p-type MOSFETs, the active layer of the fourth transistor ST4 may include an oxide semiconductor, and the active layer of each of the other transistors DT, ST1, ST2, ST3, ST5, and ST6 may include polysilicon. Also, the fourth transistor ST4 is turned on when the scan signal of the gate high voltage is applied, whereas the other transistors DT1, ST2, ST3, ST5, and ST6 may be turned on when the scan signal and the emission control signal of the gate low voltage are applied.

In an embodiment, the first to sixth transistors ST1, ST2, ST3, ST4, ST5, and ST6 and the driving transistor DT may all be formed as n-type MOSFETs. In this case, the active layer of each of the first to sixth transistors ST1, ST2, ST3, ST4, ST5, and ST6 and the driving transistor DT is formed as an oxide semiconductor, and may be turned on when the scan signal and the emission control signal of the gate high voltage are applied.

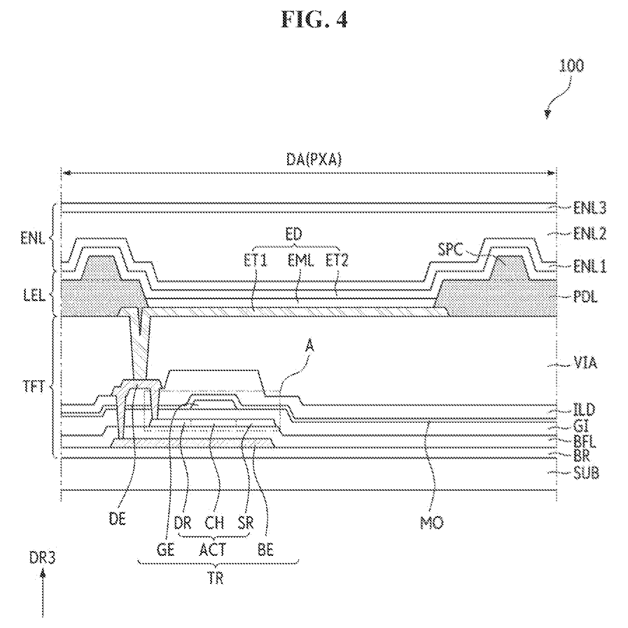

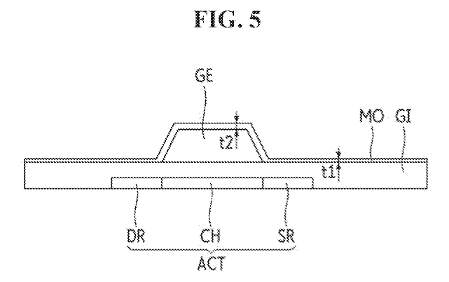

FIG. 4 is a cross-sectional view illustrating a display panel according to an embodiment. FIG. 5 is an enlarged cross-sectional view of an area A of FIG. 4, illustrating a structure of a thin-film transistor. For example, FIG. 4 shows a portion of the display area DA of the display panel 100. FIG. 4 shows a light-emitting display panel including a light-emitting element ED (e.g., an organic light-emitting diode) as an example of the display panel 100 to which embodiments are applied.

Referring to FIG. 4, the display panel 100 may include a substrate SUB (or a base layer), a thin-film transistor layer TFT, a light-emitting element layer LEL, and an encapsulation layer ENL. The thin-film transistor layer TFT, the light-emitting element layer LEL, and the encapsulation layer ENL may be disposed on the substrate SUB to overlap one another. For example, the thin-film transistor layer TFT, the light-emitting element layer LEL, and the encapsulation layer ENL may be sequentially disposed on the substrate SUB along the third direction D3 based on the display area DA.

In an embodiment, the display panel 100 may further include additional elements above and/or below the encapsulation layer ENL. For example, the display panel 100 may further include at least one of a sensor layer (e.g., a touch sensor layer), an optical layer (e.g., a color filter layer and/or a wavelength conversion layer), or a protective layer (e.g., a protective film, an insulating layer, an upper substrate and/or a window). Each of the sensor layer, the optical layer, and/or the protective layer may be disposed above the encapsulation layer ENL or between the light-emitting element layer LEL and the encapsulation layer ENL.

The substrate SUB, which is a base member for forming the display panel 100, may be rigid or flexible. In an embodiment, the substrate SUB may be a substrate including an insulating material such as glass and having rigid characteristics, and may not be bent. In an embodiment, the substrate SUB may be a flexible substrate that includes polyimide or other insulating materials and may be deformed to be subjected to bending, folding, or rolling, and may be bent or may not be bent.

The thin-film transistor layer TFT (e.g., a backplane circuit layer or a thin-film transistor layer) may be disposed on the substrate SUB. The thin-film transistor layer TFT may include circuit elements of pixels including pixel transistors and capacitors, and lines (e.g., signal lines and power lines).

In an embodiment, the transistors TR may be formed using an oxide semiconductor. In an embodiment, the transistors TR may be formed using a material having semiconductor properties. The active layers ACT of the transistors TR may be on the same layer (e.g., an upper portion of a buffer layer BFL) in the thin-film transistor layer TFT.

The thin-film transistor layer TFT may include a plurality of conductive layers and at least one semiconductor layer, which are disposed on the substrate SUB (or a barrier layer BR). In addition, the thin-film transistor layer TFT may further include a plurality of insulating layers and/or insulating patterns, which are disposed on the substrate SUB (or the barrier layer BR).

Patterns included in the conductive layers of the thin-film transistor layer TFT may include electrodes constituting circuit elements of the thin-film transistor layer TFT, conductive patterns connected to the circuit elements and/or lines. The patterns (e.g., electrodes, conductive patterns, and/or lines of respective conductive layers) included in the respective conductive layers of the thin-film transistor layer TFT may include at least one conductive material. For example, the patterns included in the respective conductive layers of the thin-film transistor layer TFT may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) or other metal, their alloy, or other conductive material. In an embodiment, the patterns included in the same conductive layer may be formed simultaneously using the same conductive material.

The patterns included in the semiconductor layer of the thin-film transistor layer TFT may include active layers ACT of transistors in the thin-film transistor layer TFT. In an embodiment, the active layers ACT of the pixel transistors and circuit unit transistors may be simultaneously formed using the same semiconductor material (e.g., oxide semiconductor). Accordingly, the active layers ACT of the transistors TR and the circuit unit transistors may be on the same layer, and may include the same semiconductor material.

Insulating layers and/or insulating patterns of the thin-film transistor layer TFT may include a barrier layer BR, a buffer layer BFL, a gate insulating layer GI, an interlayer insulating layer ILD, and a planarization layer VIA, which are sequentially disposed on the substrate SUB along the third direction D3. Each of the insulating layers and/or the insulating patterns of the thin-film transistor layer TFT may include an inorganic insulating material or an organic insulating material, and may include a single layer or multiple layers.

In an embodiment, at least one of the insulating layers of the thin-film transistor layer TFT may be entirely disposed in the display area DA. For example, the barrier layer BR, the buffer layer BFL, the interlayer insulating layer ILD, and the planarization layer VIA may be entirely disposed in the display area DA.

A structure of the thin-film transistor layer TFT will be described for each layer. First, the barrier layer BR may be disposed on the substrate SUB. The barrier layer BR may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating materials). The barrier layer BR may protect the pixels from moisture permeated through the substrate SUB that is vulnerable to moisture permeation. The barrier layer BR may be omitted in an embodiment.

A first conductive layer (e.g., a lower conductive layer) including a bottom electrode BE (or a light blocking layer) of at least one transistor may be disposed on the barrier layer BR (or the substrate SUB). For example, the bottom electrode BE (or the light blocking layer) of the transistor TR may be disposed on the barrier layer BR. The bottom electrode BE may be disposed below the active layer ACT to overlap a channel area CH of the transistor TR. In an embodiment, the bottom electrode BE may also overlap at least a portion of a source area SR and a drain area DR of the transistor TR, but is not limited thereto. Each of patterns of the first conductive layer including the bottom electrode BE includes at least one conductive material, and may include a single layer or multiple layers.

In an embodiment, the bottom electrode BE may be electrically connected to one electrode (e.g., a connection electrode CNE) of the transistor TR, and may be used as an electrode for adjusting characteristics of the transistor TR. For example, the bottom electrode BE may be electrically connected to the connection electrode CNE of the transistor TR. When the bottom electrode BE is electrically connected to one electrode of the transistor TR, the bottom electrode BE may be considered as an element included in the transistor TR. As the bottom electrode BE is below the active layer ACT of the transistor TR, external light may be prevented from being incident on the channel area CH of the transistor TR. In an embodiment, when the transistors of the thin-film transistor layer TFT do not include the bottom electrode BE or the light blocking layer, the first conductive layer may be omitted.

The buffer layer BFL may be disposed on the barrier layer BR and the bottom electrode BE. The buffer layer BFL may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating material).

The buffer layer BFL may include an insulating material suitable as a barrier material capable of preventing diffusion of oxygen or hydrogen. In addition to a silicon nitride layer including silicon nitride (SiNₓ) and a silicon oxide layer including silicon oxide (SiOₓ), the buffer layer BFL may also include other insulating materials capable of properly blocking oxygen, hydrogen and/or moisture. For example, the buffer layer BFL may include aluminum oxide (AlₓO_{y}).

In an embodiment, the buffer layer BFL may include a second metal oxide film formed by anodizing a second metal film disposed on the substrate. For example, the second metal film may include aluminum, and the second metal oxide film may include aluminum oxide formed by an anodizing method. By using anodized aluminum oxide in the buffer layer BFL, diffusion of hydrogen from the substrate side can be effectively suppressed, thereby helping protect the oxide semiconductor in the active layer ACT and contributing to stable electrical performance of the transistor TR.

The active layer ACT may include a channel area CH, a source area SR, and a drain area DR. The channel area CH overlaps the gate electrode GE in the third direction DR3 when viewed in a plan view, and may be disposed between the source area SR and the drain area DR. The source area SR and the drain area DR are positioned on respective sides of the channel area CH, and may be spaced apart from each other with the channel area CH interposed between the source area SR and the drain area DR. The source area SR and the drain area DR (or a portion of each of the source area SR and the drain area DR) may not overlap the gate electrode GE when viewed in a plan view. Carrier concentrations (e.g., electron concentrations) of the source area SR and the drain area DR may be higher than a carrier concentration of the channel area CH.

In an embodiment, the active layers ACT may include an oxide semiconductor. For example, the active layers ACT may include an oxide semiconductor including at least one of indium (In), gallium (Ga), zinc (Zn), tin (Sn), or hafnium (Hf), or other oxide semiconductor. For example, the active layers ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO) or indium-tin-gallium-zinc oxide (ITGZO), or other oxide semiconductor.

In an embodiment, the active layers ACT of some transistors among the transistors in the thin-film transistor layer TFT may be disposed on the buffer layer BFL.

In an embodiment, at least one transistor TR may be disposed in each pixel area PXA. Accordingly, a plurality of transistors TR may be disposed in the display area DA.

The gate insulating layer GI may be disposed on the active layers ACT. For example, the gate insulating layer GI may be disposed on the buffer layer BFL, and may be etched to cover a portion of the active layer ACT and expose another portion of the active layer ACT. For example, in the area in which the transistor TR is arranged, the gate insulating layer GI may cover the channel area CH of the active layer ACT included in the transistor TR and expose the source area SR and the drain area DR of the active layer ACT. In an embodiment, the gate insulating layer GI may be disposed on the buffer layer BFL to cover the entire active layer ACT and the entire buffer layer BFL.

The gate insulating layer GI may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating material).

A second conductive layer (e.g., a gate conductive layer) including a gate electrode GE may be disposed on the gate insulating layer GI. For example, the gate electrode GE of the transistor TR may be disposed on the gate insulating layer GI covering the channel area CH of the transistor TR. Each of patterns of the second conductive layer including the gate electrode GE includes at least one conductive material, and may include a single layer.

In an embodiment, the gate electrode GE may include aluminum. When the gate electrode GE includes aluminum and is exposed during an anodizing process, the aluminum in the gate electrode GE may also undergo oxidation, contributing to the formation of a metal oxide film MO with greater thickness over the gate electrode GE than over adjacent insulating layers. This configuration may support the manufacturing technique described in greater detail below and improve the structural and electrical stability of the thin-film transistor TR.

A metal oxide film MO may be disposed on the buffer layer BFL, the semiconductor layer including the active layers ACT, the gate insulating layer GI, and the second conductive layer including the gate electrode GE. The metal oxide film MO may be disposed on the buffer layer BFL to cover the semiconductor layer, the gate insulating layer GI, and the patterns of the second conductive layer. The metal oxide film MO may include aluminum oxide (AlₓO_{y}) to protect the semiconductor layer from hydrogen introduced from outside of the device. The metal oxide film MO is described in further detail below.

In an embodiment, the metal oxide film MO may be formed by anodizing an aluminum metal film disposed over the gate electrode GE and the gate insulating layer GI. During the anodizing process, both the aluminum metal film and a surface portion of the underlying gate electrode GE may be oxidized, resulting in a metal oxide film MO having a greater thickness over the gate electrode GE than over the gate insulating layer GI. This asymmetric thickness profile may provide improved hydrogen-blocking properties in target regions, for example, in regions over the gate electrode GE, which underlies the channel area CH of the active layer ACT. Additionally, the thicker aluminum oxide layer over the gate electrode GE may suppress the hilock phenomenon that can occur during high-temperature processes, thereby improving device reliability without requiring additional high-resistance metal stacks.

The interlayer insulating layer ILD may be disposed on the metal oxide film MO. The interlayer insulating layer ILD may include at least one inorganic insulating layer including an inorganic insulating material.

A third conductive layer including conductive patterns electrically connected to the connection electrode CE and/or at least some transistor TR may be disposed on the interlayer insulating layer ILD. For example, the third conductive layer may include the connection electrode CE of the transistor TR. Each of patterns of the third conductive layer includes at least one conductive material, and may include a single layer or multiple layers.

The drain electrode DE of the transistor TR may be electrically connected to the drain area DR of the transistor TR by passing through the interlayer insulating layer ILD. In an embodiment, the drain electrode DE of the transistor TR may be electrically connected to the bottom electrode BE of the transistor TR by passing through the interlayer insulating layer ILD and the buffer layer BFL.

The planarization layer VIA may be disposed on the transistor TR. For example, the planarization layer VIA may be disposed on the interlayer insulating layer ILD and the third conductive layer. The planarization layer VIA may include at least one organic insulating layer including an organic insulating material (e.g., an acrylic resin, an epoxy resin, a phenolic resin, a polyamide resin, a polyimide resin, or other organic insulating material). The planarization layer VIA may include an inorganic insulating layer or may not include an inorganic insulating layer. A surface (e.g., an upper surface) of the planarization layer VIA may be substantially flat.

The light-emitting element layer LEL may be disposed on the thin-film transistor layer TFT. For example, the light-emitting element layer LEL may be disposed on the planarization layer VIA, and may be positioned at least in the display area DA.

The light-emitting element layer LEL may include a light-emitting element ED of each of the pixels. For example, the light-emitting element layer LEL may include a pixel defining layer PDL (also referred to as a “bank”) that partitions a light emission area of each of the pixels and the light-emitting element ED positioned in each light emission area. In an embodiment, the light-emitting element layer LEL may further include a spacer SPC disposed on a portion of the pixel defining layer PDL.

Each light-emitting element ED may include a first electrode ET1 positioned in each light emission area, and a light-emitting layer EML and a second electrode ET2, which are sequentially disposed on the first electrode ET1. The first electrode ET1 of the light-emitting element ED may be electrically connected to at least one transistor TR included in the corresponding pixel by passing through the planarization layer VIA.

The first electrode ET1 of the light-emitting element ED may be a single-layered or multi-layered electrode including at least one conductive material. In an embodiment, the display panel 100 may be a top emission type display panel, and the first electrode ET1 may include a reflective electrode layer including at least one of, for example, aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr), or other reflective conductive materials.

The light-emitting layer EML of the light-emitting element ED may include a polymer material or a low molecular material. Light emitted from the light-emitting layer EML may contribute to image display.

Although FIG. 4 shows the display panel 100 in which the light-emitting layer EML of the light-emitting element ED is individually formed in each pixel area PXA, the embodiments are not limited thereto. For example, the display panel 100 may include light-emitting elements of a tandem structure, which include a light-emitting layer EML formed as a common film over the entire display area DA.

The second electrode ET2 of the light-emitting element ED may include a conductive material. In an embodiment, the second electrode ET2 may be a common film formed over the entire display area DA to cover the light-emitting layer EML and the pixel defining layer PDL. In an embodiment, the display panel 100 may be a top emission type display panel, and the second electrode ET2 may include a transparent or translucent electrode layer.

The second electrode ET2 may include a transparent conductive material (TCO), such as ITO or IZO, which is capable of transmitting light in a top emission structure, or a semi-transmissive conductive material, such as magnesium (Mg), silver (Ag), or an alloy of magnesium (Mg) and silver (Ag). When the second electrode ET2 includes a semi-transmissive conductive material, light emission efficiency of each of the light-emitting elements ED may increase due to a micro cavity.

When the second electrode ET2 includes a semi-transmissive conductive material, light emission efficiency of each of the light-emitting elements ED may increase due to a micro cavity.

The pixel defining layer PDL has an opening corresponding to each light emission area, and may surround the light emission area. For example, the pixel defining layer PDL may be formed to cover an edge portion of the first electrode ET1 of the light-emitting element ED, and may include an opening exposing the remaining portion of the first electrode ET1. An area in which the exposed first electrode ET1 overlaps the light-emitting layer EML may be a light emission area of each pixel. In an embodiment, the pixel defining layer PDL may include an organic material. The pixel defining layer may include a light blocking material. The pixel defining layer PDL includes a base resin and a colorant. The base resin may include at least one of, for example, a cardo-based resin, an epoxy-based resin, an acrylate-based resin, a siloxane-based resin, or polyimide. The colorant may be selected from a carbon-based pigment, a metal oxide-based pigment, and an organic-based pigment. For example, the carbon-based pigment may be selected from carbon black, carbon nanotubes, titanium black, and vertically aligned nanotube arrays (VANTA) black, but is not limited thereto. For example, the metal oxide-based pigment may be a titanium black (TiNxOy) or Cu-Mn-Fe-based black pigment, but is not limited thereto. For example, the organic pigment may be selected from lactam black, perylene black, and aniline black, but is not limited thereto. In an embodiment, the colorant may be a mixture of two or more pigments or dyes having different colors, but is not limited thereto.

The spacer SPC may be disposed on a portion of the pixel defining layer PDL. The spacer SPC may include at least one organic insulating layer including an organic insulating material. The spacer SPC may include the same material as that of the pixel defining layer PDL or a different material from the pixel defining layer PDL. The pixel defining layer PDL and the spacer SPC may be sequentially formed through each mask process, or may be simultaneously and/or integrally formed using a halftone mask.

The encapsulation layer ENL may be disposed on the light-emitting element layer LEL. The encapsulation layer ENL may cover the light-emitting element layer LEL in the display area DA, and may extend to the non-display area NDA to be in contact with the thin-film transistor layer TFT. The encapsulation layer ENL may block permeation of oxygen or moisture into the light-emitting element layer LEL, and may mitigate electrical and/or physical impact to the thin-film transistor layer TFT and the light-emitting element layer LEL.

In an embodiment, the encapsulation layer ENL may include a first encapsulation layer ENL1, a second encapsulation layer ENL2, and a third encapsulation layer ENL3, which are sequentially disposed on the light-emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

Referring to FIG. 5, it may be noted that the gate insulating layer GI is to entirely cover the semiconductor layer ACT, the gate electrode GE overlapping the channel area CH of the semiconductor layer ACT is on the gate insulating layer GI in the third direction, and the metal oxide film MO is to cover the entire gate insulating layer GI and the gate electrode GE.

The semiconductor layer ACT may include an oxide semiconductor. When the oxide semiconductor layer is formed, oxygen defects may occur due to the release of oxygen existing in an excessive state. As the amount of hydrogen in the oxide semiconductor increases due to hydrogen introduced from the outside or inside, the charge mobility of the semiconductor layer ACT including the oxide semiconductor may increase. For this reason, electrical properties (e.g., threshold voltage) of the thin-film transistor layer TFT may be fluctuated, whereby reliability may be deteriorated.

In order to prevent hydrogen from flowing into the semiconductor layer ACT including the oxide semiconductor, aluminum oxide (AlₓO_{y}), titanium (Ti), or the like through which hydrogen does not pass may be on the gate electrode GE. When the metal oxide film MO is formed on the gate electrode GE, a deposition method such as atomic layer deposition (ALD), sputtering, or the like may be used. The ALD method has problems in that a deposition rate is very slow and it is difficult to form a large area. The sputtering method has problems in that a deposition rate is faster than that of the ALD method, but a process rate is slow and particles occur.

The present disclosure may effectively block the inflow of hydrogen by forming a metal oxide film MO by an anodizing method. In particular, when the anodizing method is used, there are advantages in that the process is fast and the metal oxide film MO is densely formed. Since the metal oxide film MO may effectively block hydrogen, reliability of the thin-film transistor layer TFT may be improved.

In the anodizing method according to an embodiment, both the metal film disposed over the gate insulating layer GI and the underlying gate electrode GE, which may also include aluminum, may participate in the oxidation process. As a result, the metal oxide film MO formed on the gate electrode GE may include an oxide layer not only from the deposited metal film but also from the oxidized portion of the gate electrode GE itself. This may result in a thicker metal oxide film MO over the gate electrode GE than over the adjacent gate insulating layer GI. This increased thickness above the gate electrode GE may enhance hydrogen blocking, including in a region(s) most susceptible to hydrogen-induced reliability degradation, e.g., the channel area CH of the semiconductor layer ACT.

The gate electrode GE and the metal oxide film MO may include the same metal. For example, the gate electrode GE and the metal oxide film MO may include aluminum (Al). The metal oxide film MO may include aluminum oxide (AlₓO_{y}) made by oxidizing aluminum (Al).

A thickness t₂ of the metal oxide film MO on the gate electrode GE may be greater than a thickness t₁ of the metal oxide film MO on the gate insulating layer GI.

In an embodiment, the difference in thickness between the portions of the metal oxide film MO formed on the gate electrode GE and on the gate insulating layer GI may be controlled by adjusting anodization conditions such as, e.g., voltage, reaction time, and temperature. These parameters may influence the depth to which the gate electrode GE is oxidized during the anodization process. Accordingly, the thickness t₂ of the metal oxide film MO on the gate electrode GE may be tuned to achieve a desired hydrogen barrier performance and thermal stability.

The thickness of the metal oxide film MO may be 100 Å or more. The thickness of the metal oxide film MO may be a thickness sufficient to block hydrogen. For example, when the thickness t₁ of the metal oxide film MO on the gate insulating layer GI is 400 Å, the thickness t₂ of the metal oxide film MO on the gate electrode GE may be 800 Å̊.

In case of aluminum (Al), heat resistance is low, whereby a hilock phenomenon in which a portion of aluminum (Al) is protruded upward may occur due to thermal expansion in a high-temperature process. When metal with strong heat resistance, such as titanium (Ti), is additionally stacked to prevent the hilock phenomenon, the process may be complicated or resistance of the thin-film transistor layer TFT may increase.

The present disclosure may prevent the hilock phenomenon by thickly arranging the metal oxide film MO on the gate electrode GE including aluminum (Al).

Accordingly, in an embodiment, by forming a thick aluminum oxide layer on the gate electrode GE through anodization, the display device can simultaneously suppress the hilock phenomenon caused by thermal expansion of aluminum, and preserve low electrical resistance in the gate electrode GE. In contrast to a comparative example, which may add a second metal layer such as titanium for thermal stability, thereby increasing process complexity and resistance, embodiments of the present disclosure may provide improved reliability with reduced or minimal impact on electrical characteristics and fabrication cost.

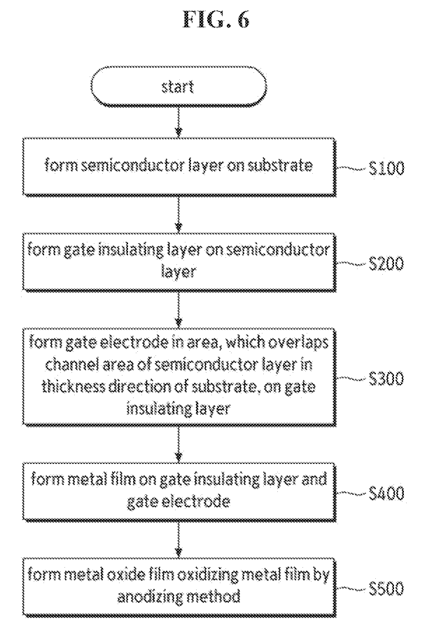

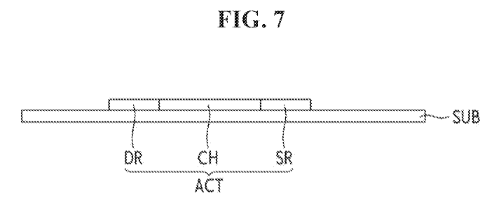

FIG. 6 is a flowchart illustrating a method of manufacturing a display device according to an embodiment. FIG. 7 is a cross-sectional view illustrating a substrate and a semiconductor layer in operation S100 of FIG. 6.

First, a semiconductor layer ACT may be formed on the substrate SUB (S100). The semiconductor layer ACT may be formed using an oxide semiconductor, and a process method used to form the semiconductor layer ACT is not limited.

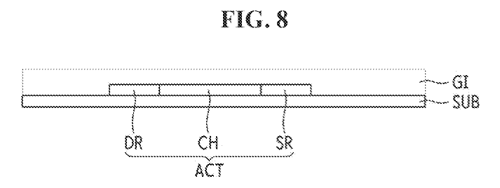

FIG. 8 is a cross-sectional view illustrating a substrate, a semiconductor layer, and a gate insulating layer in operation S200 of FIG. 6.

The gate insulating layer GI may be formed on the semiconductor layer ACT (S200). The gate insulating layer GI may be formed by using the above-exemplified material, and a process method used to form the gate insulating layer GI is not limited.

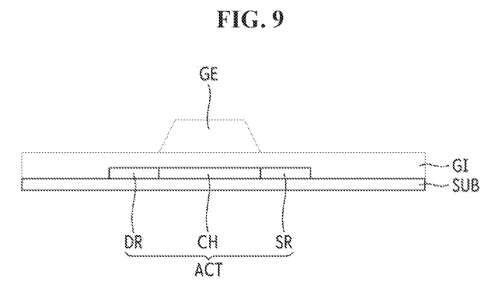

FIG. 9 is a cross-sectional view illustrating a substrate, a semiconductor layer, a gate insulating layer, and a gate electrode in operation S300 of FIG. 6.

The gate electrode GE may be formed in an area, which overlaps the channel area CH of the semiconductor layer ACT in the third direction DR3, on the gate insulating layer GI (S300). The gate electrode may be formed using aluminum (Al), and a process method used to form the gate electrode GE is not limited.

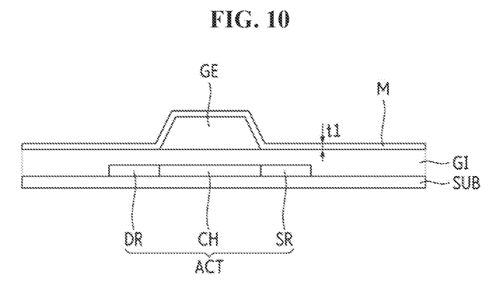

FIG. 10 is a cross-sectional view showing a substrate, a semiconductor layer, a gate insulating layer, a gate electrode, and a metal film in operation S400 of FIG. 6.

A metal film M may be formed on the gate insulating layer GI and the gate electrode GE (S400). The metal film M may be formed using aluminum (Al). A process method used to form the metal film M is not limited. For example, the metal film M may be formed by a deposition process.

A thickness t₁ of the metal film M may be about 100 Å or more. The thickness of the metal film M formed on the gate insulating layer GI and the thickness of the metal film M formed on the gate electrode GE may be about the same as t₁.

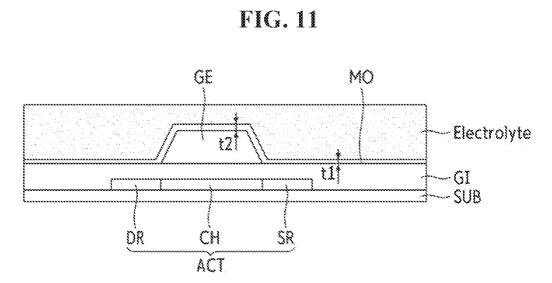

FIG. 11 is a cross-sectional view illustrating a substrate, a semiconductor layer, a gate insulating layer, a gate electrode, and a metal oxide film in operation S500 of FIG. 6.

The metal film M may be oxidized by an anodizing method to form the metal oxide film MO (S500). When the gate electrode GE and the metal film M are aluminum (Al), the metal oxide film MO may be oxidized to aluminum oxide (AlₓO_{y}). A thickness t₁ of the metal oxide film MO formed on the gate insulating layer GI may be about the same as the thickness t₁ of the metal film M. A thickness t₂ of the metal oxide film MO formed on the gate electrode GE may be greater than the thickness t₁ of the metal film M. For example, when the thickness t₁ of the metal film M is about 400 Å ̊, the thickness t₁ of the metal oxide film formed on the gate insulating layer GI may be about 400 Å, and the thickness t₂ of the metal oxide film MO formed on the gate electrode GE may be about 800 Å. A reason that the thickness t₂ of the metal oxide film MO formed on the gate electrode GE is thicker is that not only the metal film M but also the metal of the gate electrode GE is oxidized on the gate electrode GE to form the metal oxide film MO. The thickness t₂ of the metal oxide film MO formed on the gate electrode GE may be controlled by reaction conditions such as, for example, reaction time, temperature, and voltage intensity during anodization.

Aluminum (Al) may become aluminum oxide (AlₓO_{y}) by reacting with oxygen in the atmosphere. A thickness of the aluminum oxide (AlₓO_{y}) film formed by oxygen in the atmosphere is about 30 Å to about 50 Å. However, this thickness is relatively thin, and thus, it may be difficult to block hydrogen. In embodiments according to the present disclosure, the metal oxide film MO is formed with a sufficient thickness to block hydrogen and is then oxidized to form the metal oxide film MO. Moreover, since a metal oxide is densely formed in the metal oxide film MO oxidized by the anodizing method, hydrogen may be effectively blocked.

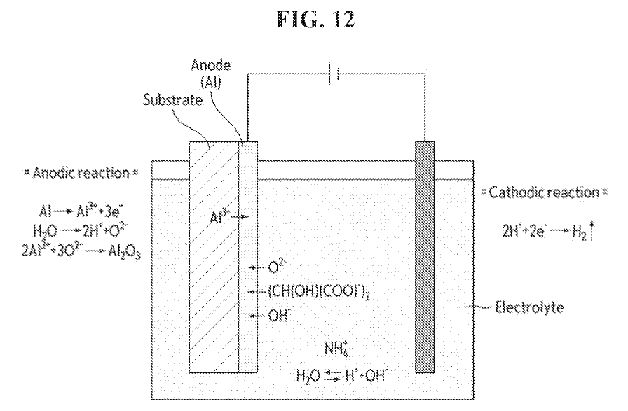

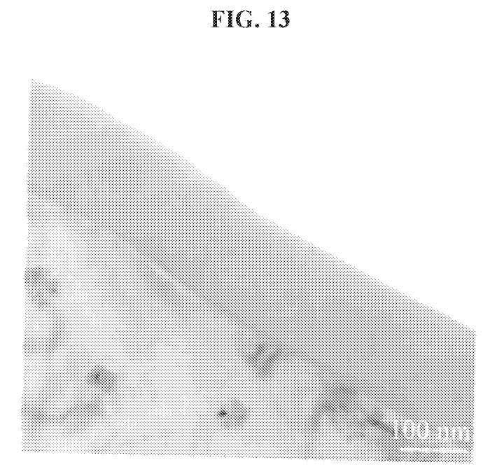

FIG. 12 is a schematic diagram illustrating a method of anodizing aluminum. FIG. 13 is a transmission electron microscope (TEM) image of a cross-section of anodized aluminum.

Referring to FIG. 12, there is water containing an electrolyte in a reaction vessel and aluminum is connected to an anode. The electrolyte may include, for example, tartaric acid of about 3 wt%, ethylene glycol, and a small amount of ammonium. The water in the reaction vessel may have a pH of about 6.5 to about 7.5. When a voltage is applied, anions such as O²⁻, OH⁻ and (CH(OH)(COO)⁻)₂ move to the anode, and a cation such as H⁺ moves to the cathode. Aluminum connected to the anode is oxidized to aluminum oxide (Al₂O₃) by reacting with the moved anions.

Referring to FIG. 13, it can be seen that aluminum oxide (Al₂O₃) formed on aluminum is formed in a dense structure.

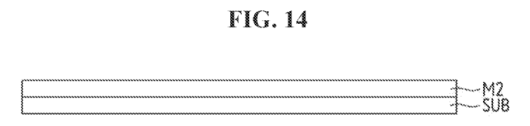

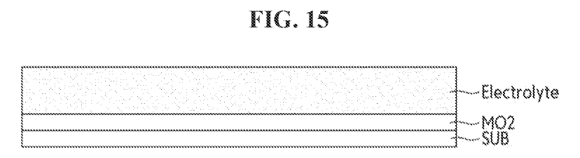

FIG. 14 is a cross-sectional view illustrating a substrate and a second metal film. FIG. 15 is a view illustrating that a second metal film formed on a substrate is oxidized to a second metal oxide film using an anodizing method.

Before the semiconductor layer ACT is formed, a second metal film M2 may be formed on the substrate SUB. Subsequently, the second metal film M2 formed on the substrate SUB may be oxidized to a second metal oxide film MO by an anodizing method. Subsequently, the semiconductor layer ACT may be formed on the second metal oxide film MO.

The second metal oxide film MO may be formed as the buffer layer BFL. When the buffer layer BFL is formed as the second metal oxide film MO, hydrogen flowing into the semiconductor layer ACT from a direction opposite to the third direction DR3 (e.g., a lower portion of the substrate SUB) may be also blocked.

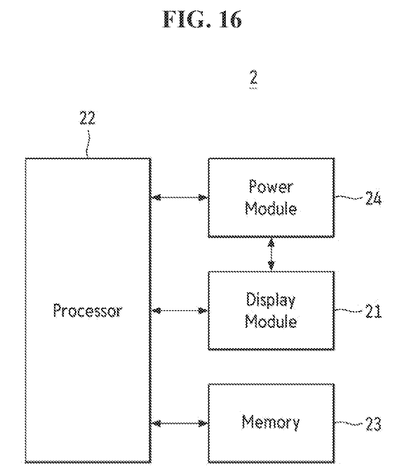

FIG. 16 is a block diagram illustrating an electronic device according to an embodiment. Referring to FIG. 16, an electronic device 2 according to an embodiment may include a display module 21, a processor 22, a memory 23, and a power module 24.

The processor 22 may include at least one of, for example, a central processing unit (CPU), an application processor (AP), a graphic processing unit (GPU), a communication processor (CP), an image signal processor (ISP), or a controller.

Data utilized for an operation of the processor 22 or the display module 21 may be stored in the memory 23. When the processor 22 executes an application stored in the memory 23, an image data signal and/or an input control signal is transmitted to the display module 21, and the display module 21 may process the received signal and output image information through a display screen.

The power module 24 may include a power supply module such as a power adapter or a battery device, and a power conversion module that converts a power source supplied by the power supply module to generate a power source utilized for the operation of the electronic device 2.

At least one of the respective components of the above-described electronic device 2 may be included in the display device 1 according to the above-described embodiments. Also, some of the individual modules functionally included in one module may be included in the display device 1, and others thereof may be provided separately from the display device 1. For example, in an embodiment, the display device 1 may include the display module 21, and the processor 22, the memory 23 and the power module 24 may be provided as devices in the electronic device 2 other than the display device 1.

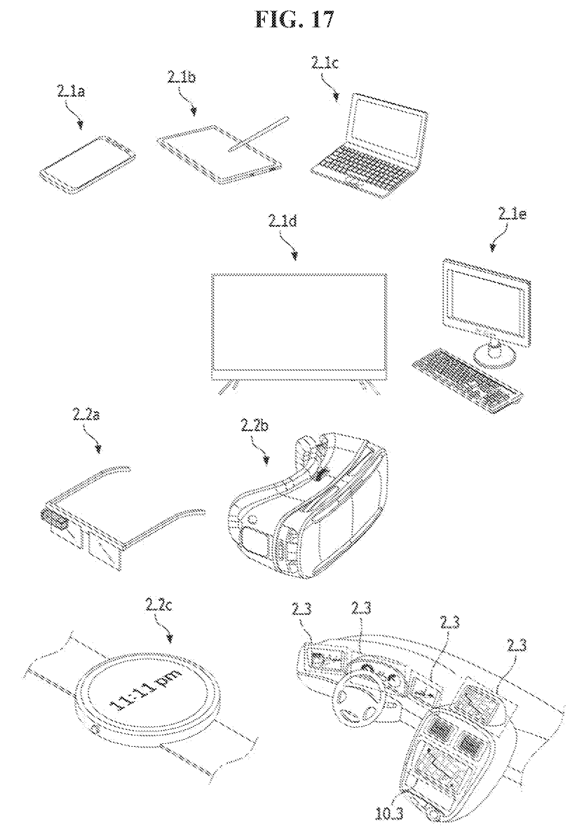

FIG. 17 illustrates schematic diagrams of an electronic device according to various embodiments.

Referring to FIG. 17, various electronic devices 2 to which the display devices according to embodiments are applied may include not only electronic devices for image display, such as a smartphone 2_1a, a tablet computer 2_1b, a laptop 2_1c, a TV 2_1d, and a computer monitor 2_1e, but also wearable electronic devices including display modules such as smart glasses 2_2a, a head mounted display 2_2b, and a smart watch 2_2c, and a vehicle electronic device 2_3 including display modules such as a vehicle dashboard, a center fascia, a center information display (CID) on the dashboard, and a room mirror display.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a substrate;
a semiconductor layer disposed on the substrate;
a gate electrode that overlaps a channel area of the semiconductor layer in a thickness direction of the substrate;
a gate insulating layer disposed between the semiconductor layer and the gate electrode and insulating the semiconductor layer from the gate electrode; and
a metal oxide film disposed on the gate electrode and the gate insulating layer,
wherein a first thickness of the metal oxide film disposed on the gate electrode is greater than a second thickness of the metal oxide film disposed on the gate insulating layer.

2. The display device of claim 1, wherein the gate electrode comprises aluminum (Al).

3. The display device of claim 2, wherein the metal oxide film comprises aluminum oxide (AlₓO_{y}).

4. The display device of claim 3, wherein the metal oxide film is formed an anodizing method.

5. The display device of claim 1, wherein the semiconductor layer comprises an oxide semiconductor.

6. The display device of claim 1, wherein a thickness of the metal oxide film is about 100 Å or more.

7. The display device of claim 1, further comprising:
a buffer layer disposed between the substrate and the semiconductor layer and comprising anodized aluminum oxide (AlₓO_{y}7).

8. A method of manufacturing a display device, the method comprising:
forming a semiconductor layer on a substrate;
forming a gate insulating layer on the semiconductor layer;
forming a gate electrode on the gate insulating layer in an area which overlaps a channel area of the semiconductor layer in a thickness direction of the substrate;
forming a metal film on the gate insulating layer and the gate electrode; and
forming a metal oxide film by oxidizing the metal film using an anodizing method.

9. The method of claim 8, wherein a first thickness of the metal oxide film formed on the gate electrode is greater than a second thickness of the metal oxide film formed on the gate insulating layer.

10. The method of claim 8, wherein the gate electrode and the metal film comprise a same metal.

11. The method of claim 10, wherein the gate electrode comprises aluminum (Al).

12. The method of claim 11, wherein the metal oxide film comprises aluminum oxide (AlₓO_{y}).

13. The method of claim 8, wherein the semiconductor layer comprises an oxide semiconductor.

14. The method of claim 8, wherein a thickness of the metal oxide film is about 100 Å or more.

15. The method of claim 8, further comprising:
before forming the semiconductor layer, forming a second metal film on the substrate before forming a semiconductor layer; and
before forming the semiconductor layer, forming a second metal oxide film by oxidizing the second metal film using the anodizing method.

16. The method of claim 15, wherein the second metal film comprises aluminum (Al), and the second metal oxide film comprises aluminum oxide (AlₓO_{y}).

17. An electronic device, comprising:
a display device configured to provide an image; and
a processor configured to transmit an image data signal to the display device,
wherein the display device comprises:
a substrate;
a semiconductor layer disposed on the substrate;
a gate electrode that overlaps a channel area of the semiconductor layer in a thickness direction of the substrate;
a gate insulating layer disposed between the semiconductor layer and the gate electrode and insulating the semiconductor layer from the gate electrode; and
a metal oxide film disposed on the gate electrode and the gate insulating layer,
wherein a first thickness of the metal oxide film disposed on the gate electrode is greater than a second thickness of the metal oxide film disposed on the gate insulating layer.

18. The electronic device of claim 17, wherein the gate electrode comprises aluminum (Al), and the metal oxide film comprises aluminum oxide (AlₓO_{y}).

19. The electronic device of claim 18, wherein the metal oxide film is formed using an anodizing method.

20. The electronic device of claim 17, wherein the semiconductor layer comprises an oxide semiconductor.
